(19) United States
(12) Patent Application Publication
(10) Pub. No.: US 2024/0105378 A1
(43) Pub. Date: Mar. 28, 2024

(54) PLANAR TRANSFORMER AND CONVERTER HAVING SAME

(71) Applicants: Hyundai Motor Company, Seoul (KR); Kia Corporation, Seoul (KR)

(72) Inventors: Dae Woo LEE, Incheon (KR); Sang Jin KIM, Hwaseong-si (KR); Tae Jong HA, Seoul (KR); Byung Gu KANG, Hwaseong-si (KR)

(73) Assignees: Hyundai Motor Company, Seoul (KR); Kia Corporation, Seoul (KR)

(21) Appl. No.: 18/098,890

(22) Filed: Jan. 19, 2023

(30) Foreign Application Priority Data
Sep. 27, 2022 (KR) 10-2022-0122703

(51) Int. Cl. H01F 27/28; H01F 27/24; H01F 27/30; H02M 3/335

(52) U.S. Cl. CPC H01F 27/2804; H01F 27/24; H01F 27/306; H02M 3/33576; H01F 2027/2819

(57) ABSTRACT

A planar transformer and a converter including the same include a first core unit including a first receiving portion extending in a first direction; a second core unit spaced from the first core unit, disposed in parallel with the first core unit in a second direction thereof, and including a second receiving portion extending in the first direction; a first coil unit including a first through hole formed in a center portion thereof and a first coil pattern passing through the first receiving portion and the second receiving portion around the first through hole to form a turn; and a second coil unit including a second through hole formed in a center portion thereof and aligned with the first through hole in a third direction thereof, and a second coil pattern passing through the first receiving portion and the second receiving portion around the second through hole.

### CROSS REFERENCE TO RELATED APPLICATION

The present application claims priority to Korean Patent Application No. 10-2022-0122703 filed on Sep. 27, 2022, the entire contents of which is incorporated herein for all purposes by this reference.

### BACKGROUND OF THE PRESENT DISCLOSURE

### Field of the Present Disclosure

The present disclosure relates to a planar transformer including a plurality of core units and a converter including the same.

### Description of Related Art

Recently, in response to the crisis of air pollution and oil depletion, technologies related to eco-friendly vehicles using electrical energy as vehicle power have been actively developed. An eco-friendly vehicle includes a hybrid electric vehicle (HEV), an electric vehicle (EV), and a fuel cell electric vehicle (FCEV).

The eco-friendly vehicle may include a battery charged with electrical energy, and may use the electrical energy stored in the battery for driving the vehicle or driving the vehicle electrical components. The eco-friendly vehicle may be provided with a converter for converting or charging power of a battery, and a transformer may be provided in the circuit of the converter. Recently, to reduce the cost and improve ease of the manufacture, research on replacing a transformer with a planar transformer has been actively conducted.

Meanwhile, an eco-friendly vehicle may require a DC/DC converter of medium or large capacity that transfers power from a high voltage terminal to a low voltage output terminal, and various types of resonant converters for achieving high efficiency and high power density may be applied. Among them, a phase shift full bridge (PSFB) converter is capable of zero voltage switching (ZVS) through soft switching of active elements without any additional circuits, and is widely used because the ripple of an output current may be reduced through an output LC filter.

However, the output terminal of the PSFB converter is usually provided with an output inductor. As the current path lengthens due to the output inductor, the loss of current may increase, reducing the efficiency of the PSFB converter.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a planar transformer having a plurality of core units and a converter configured for using one of the core units to perform a function of an output inductor.

The technical objects to be achieved by the present disclosure are not limited to the above-mentioned technical objects, and the other technical objects not mentioned may be clearly understood by those skilled in the art from the following descriptions.

According to one aspect of the present disclosure, a planar transformer includes a first core unit including a first receiving portion extending in a first direction thereof; a second core unit spaced from the first core unit, disposed in parallel with the first core unit in a second direction thereof, and including a second receiving portion extending in the first direction thereof; a first coil unit including a first through hole formed in a center portion thereof and a first coil pattern passing through the first receiving portion and the second receiving portion around the first through hole to form a turn; and a second coil unit including a second through hole formed in a center portion thereof and aligned with the first through hole in a third direction thereof, and a second coil pattern passing through the first receiving portion and the second receiving portion around the second through hole.

For example, the first core unit may include a (1-1)-th leg and a (1-2)-th leg extending in the third direction and spaced from each other in the second direction, and the second core unit may include a (2-1)-th leg and a (2-2)-th leg extending in the third direction and spaced from each other in the second direction thereof.

For example, the (1-2)-th leg and the (2-1)-th leg may face each other in the second direction thereof.

For example, the (1-2)-th leg and the (2-1)-th leg may pass through the first through hole and the second through hole in the third direction thereof.

For example, the first core unit may include a first upper core and a first lower core coupled to each other in the third direction, and the second core unit may include a second upper core and a second lower core coupled to each other in the third direction thereof.

For example, the first coil unit may include a plurality of first printed circuit boards stacked in the third direction thereof.

For example, the second coil unit may include a plurality of second printed circuit boards spaced from each other in the third direction thereof.

According to another aspect of the present disclosure, a converter includes one of the above-described planar transformers; a primary switching unit including an AC terminal connected to one end portion of the planar transformer and a DC terminal receiving DC power, the primary switching unit including a plurality of first switching elements; and a secondary rectifying unit including one end portion connected to an opposite end portion of the planar transformer and an opposite end portion connected to an output end portion.

For example, the converter may further include a substrate, wherein the secondary rectifying unit is disposed in a center portion of the substrate, the primary switching unit is disposed at one side of the secondary rectifying unit on the substrate, and the transformer is disposed at an opposite side of the rectifying unit on the substrate.

According to the planar transformer and the converter including the same of the present disclosure, the planar transformer core is configured with the plurality of core units and the planar transformer is applied to the converter, so that the output inductor included in the output terminal of the converter is not required, reducing the cost.

Furthermore, it is possible to minimize the current flow length due to the removal of the output inductor, so that the current loss at the output stage of the converter may be reduced, improving efficiency.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 and FIG. 2 are perspective views exemplarily illustrating the configuration of a planar transformer according to an exemplary embodiment of the present disclosure.

FIG. 3 is a cross-sectional view of a planar transformer according to an exemplary embodiment of the present disclosure.

FIG. 4 is a circuit diagram illustrating the configuration of a converter according to an exemplary embodiment of the present disclosure.

FIG. 5 is a diagram illustrating a configuration of a substrate included in a converter according to an exemplary embodiment of the present disclosure.

FIG. 6 and FIG. 7 are diagrams illustrating circuit changes of a converter according to an exemplary embodiment of the present disclosure.

FIGS. 8A and 8B are diagrams illustrating a current flow flowing through a first coil unit in a planar transformer according to an exemplary embodiment of the present disclosure.

FIG. 9 is a diagram illustrating a current flow flowing through a second coil unit in a planar transformer according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION OF THE PRESENT DISCLOSURE

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

In describing the exemplary embodiments of the present specification, when a specific description of related art is deemed to obscure the subject matter of the exemplary embodiments of the present specification, the detailed description will be omitted. Furthermore, the accompanying drawings are intended to facilitate the understanding of the exemplary embodiments set forth in the present specification, and the technical idea of the present specification is not limited by the accompanying drawings. All alterations, equivalents, and substitutes that are included within the technical idea of the present disclosure should be understood as falling within the scope of the present disclosure.

The ordinal number terms such as first, second, and the like may be used to describe various constituent elements but should not limit these constituent elements. These terms are only used to distinguish one constituent element from another element.

It should be understood that a constituent element, when referred to as being “connected to” or “coupled to” another constituent element, may be directly connected or directly coupled to another constituent element or may be connected or coupled to another constituent element with a third constituent element disposed therebetween. In contrast, it should be understood that a constituent element, when referred to as being “directly connected to” or “directly coupled to” another constituent element, is connected or coupled to another constituent element without a third constituent element therebetween.

A noun in singular form has the same meaning as nouns when used in plural form, unless it has a different meaning in context.

It should be understood that, throughout the present specification, the term “include”, “have” or the like is directed to indicate that a feature, a number, a step, an operation, a constituent element, a component, or a combination thereof mentioned in the specification is present, without precluding the possibility that one or more other features, numbers, steps, operations, constituent elements, components, or a combination thereof will be present or added.

Hereinafter, embodiments included in the present specification will be described in detail with reference to the accompanying drawings. However, regardless of the reference character, the same or similar constituent elements shall be provided the same reference number and the redundant descriptions thereof shall be omitted. Various exemplary embodiments are described using a coordinate system, and axes 1, 2, and 3 shown in each figure in the coordinate system are orthogonal to each other, but the exemplary embodiment of the present disclosure is not limited thereto. For example, axis 1, axis 2, and axis 3 may cross each other.

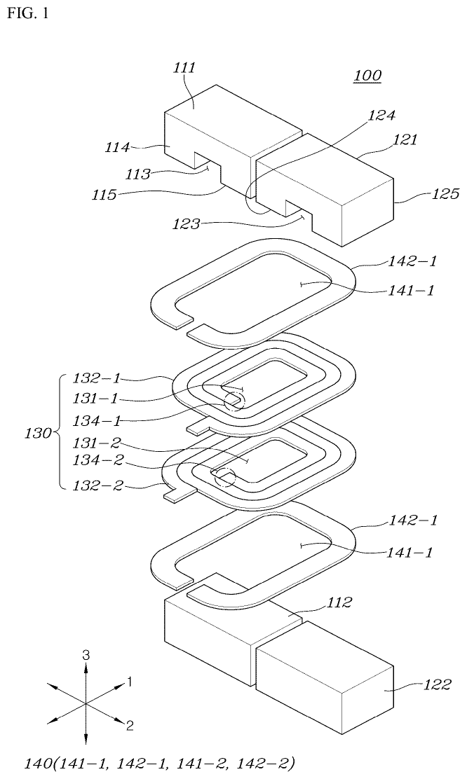

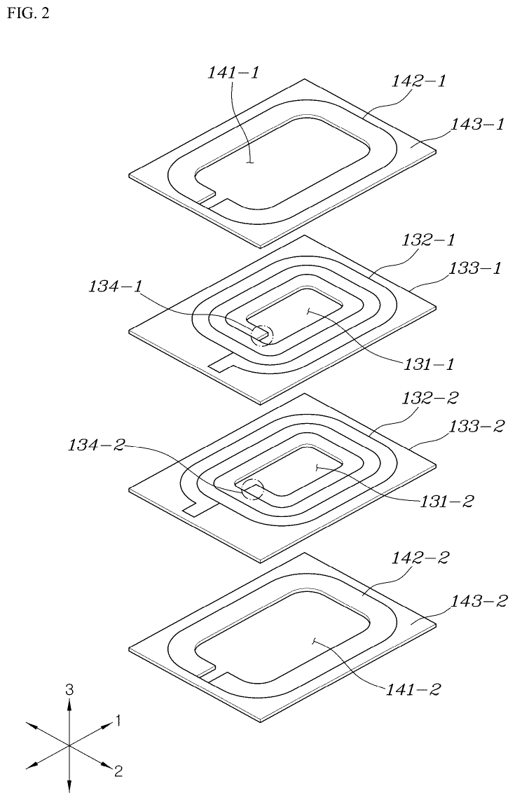

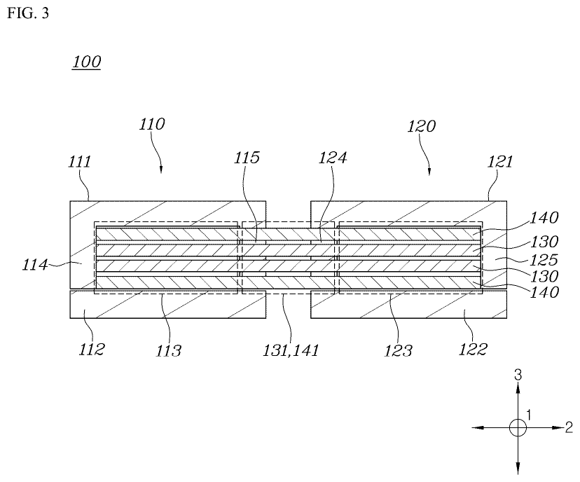

Hereinafter, a planar transformer according to an exemplary embodiment of the present disclosure will be described with reference to FIG. 1, FIG. 2, and FIG. 3.

FIG. 1 and FIG. 2 are perspective views exemplarily illustrating the configuration of a planar transformer according to an exemplary embodiment of the present disclosure. FIG. 3 is a cross-sectional view of a planar transformer according to an exemplary embodiment of the present disclosure.

Referring to FIG. 1, FIG. 2, and FIG. 3, a planar transformer 100 according to various exemplary embodiments of the present disclosure may include core units 110 and 120 and coil units 130 and 140. Hereinafter, each component will be described in detail.

First, the core units 110 and 120 will be described with reference to FIGS. 1 and 3. The planar transformer 100 of the present disclosure may include a plurality of core units 110 and 120. The plurality of core units 110 and 120 may include the first core unit 110 and the second core unit 120 disposed in parallel with the first core unit 110 in a second direction (i.e., the direction of axis 2) while being spaced from the first core unit 110. Each of the core units 110 and 120 may have a property of a magnetic circuit to serve as a passage for magnetic flux.

Furthermore, each of the core units 110 and 120 may include upper cores 111 and 121 and lower cores 112 and 122 coupled to each other in a third direction (i.e., the direction of axis 3). The upper cores 111 and 121 and the lower cores 112 and 122 forming each of the core units may have shapes which are vertically symmetrical to each other, or may have asymmetrical shapes. Furthermore, each of the core units 110 and 120 may have receiving portions 113 and 123 extending in a first direction (i.e., the direction of axis 1).

Referring to FIG. 3, each of the core units 110 and 120 may have a plurality of legs 114, 115, 124 and 125 that extend in a third direction and are spaced from each other in the second direction thereof. For example, the first core unit 110 may have a (1-1)-th leg 114 and a (1-2)-th leg 115 that extend in the third direction and are spaced from each other in the second direction thereof. Furthermore, the second core unit 120 may have a (2-1)-th leg 124 and a (2-2)-th leg 125 that extend in the third direction and are spaced from each other in the second direction thereof. Furthermore, because the first and second core units 110 and 120 are disposed in parallel with each other in the second direction, the (1-2)-th legs 115 of the first core unit 110 and the (2-1)-th leg 124 of the second core unit 120 may face each other in the second direction thereof.

Furthermore, the (1-1)-th leg 114 and the (1-2)-th leg 115 may extend in the third direction from the first upper core 111 or the first lower core 112 of the first core unit 110. The (2-1)-th leg 124 and the (2-2)-th leg 125 may also extend in the third direction from the second upper core 121 or the second lower core 122 of the second core unit 120. For example, according to an exemplary embodiment of the present disclosure, as shown in FIG. 3, the (1-1)-th leg 114 and the (1-2)-th leg 115 may extend from the first upper core 111 of the first core unit 110 in the third direction, and the (2-1)-th leg 124 and the (2-2)-th leg 125 may extend from the second upper core 121 of the second core unit 120 in the third direction thereof. Accordingly, it may be assumed that the upper cores 111 and 121 and the lower cores 112 and 122 of each of the core units 110 and 120 according to an exemplary embodiment of the present disclosure have shapes asymmetrical with each other. However, this is only an example and is not necessarily limited thereto.

Referring to FIG. 1, the first and second coil units 130 and 140 may have a first through hole 131 and a second through hole 141 in the center portions, respectively. Referring to FIG. 3, the (1-2)-th leg 115 of the first core unit 110 and the (2-1)-th leg 124 of the second core unit 120 may pass through the first and second through holes 131 and 141 in the third direction thereof. That is, the (1-2)-th leg 115 and the (2-1)-th leg 124 pass through the first and second through holes 131 and 141 so that the first and second coil units 130 and 140 may be aligned in the third direction thereof.

In an exemplary embodiment of the present invention, the first through holes 131 include an upper through hole 131-1 and a lower through hole 131-2.

In an exemplary embodiment of the present invention, the second through holes 141 include an upper through hole 141-1 and a lower through hole 141-2.

Meanwhile, because the plurality of core units 110 and 120 surround portions of the first and second coil units 130 and 140, it may be seen that portions of the first and second coil units 130 and 140 forming the coil units 130 and 140 are disposed within the core units. That is, as shown in FIG. 3, portions of the first and second coil units 130 and 140 may be disposed in the first receiving portion 113 of the first core unit 110, and portions of the first and second coil units 130 and 140 may be disposed in the second receiving portion 123 of the second core unit 120. Accordingly, the planar transformer 100 of the present disclosure has the plurality of core units 110 and 120 so that it is possible to form a plurality of planar transformers performing the same function.

Hereinafter, the coil units 130 and 140 will be described with reference to FIG. 1 and FIG. 2. In FIG. 1, for convenience of explanation, the shapes of the coil units 130 and 140 included in the planar transformer 100 are expressed only as coil patterns, and the shapes of the coil units 130 and 140 forming the planar transformer 100 according to an exemplary embodiment of the present disclosure may be the same as in FIG. 2.

Referring to FIG. 1, the coil units 130 and 140 may include a first coil unit 130 and a second coil unit 140. The first coil unit 130 may have a first coil pattern 132 which passes through the first receiving portion 113 of the first core unit 110 and the second receiving portion 123 of the second core unit 120 around the first through hole 131 to form a turn. Furthermore, the second coil unit 140 may have a second coil pattern 142 which passes through the first receiving portion 113 of the first core unit 110 and the second receiving portion 123 of the second core unit 120 around the second through hole 141.

For example, the first coil unit 130 may form a primary side coil in the planar transformer 100, and the second coil unit 140 may form a secondary side coil in the planar transformer 100. Of course, according to implementation, the first coil unit 130 may form the secondary side coil of the planar transformer 100, and the second coil unit 140 may form the primary side coil of the planar transformer 100. However, the embodiment of the present disclosure is exemplary, and the present disclosure is not necessarily limited thereto.

The coil patterns of the first and second coil units 130 and 140 may be divided into a plurality of portions in the third direction, and for convenience of explanation, may be exemplarily divided into upper and lower portions. The first coil pattern 132 may have a first upper coil pattern 132-1 and a first lower coil pattern 132-2 that form a plurality of turns, respectively. The first upper and lower coil patterns 132-1 and 132-2 may have a same rotation direction so that the numbers of turns are summed.

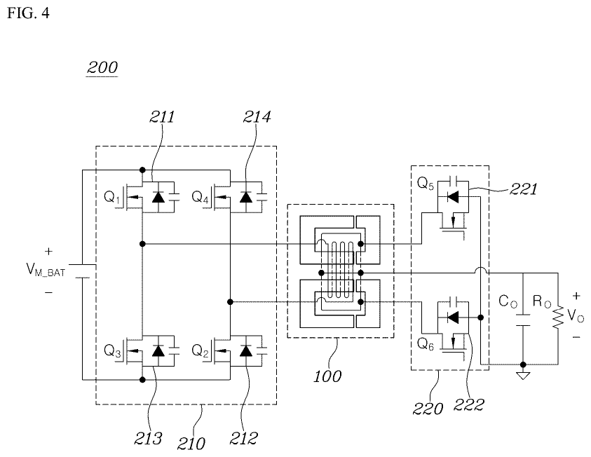

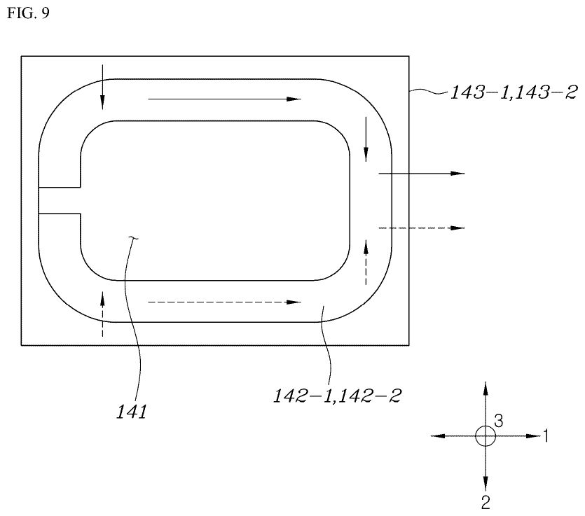

Unlike the first coil pattern 132, the second coil pattern 142 may be formed in a single pattern rather than a pattern forming a plurality of turns. Furthermore, the second coil pattern 142 may include the second upper and lower coil patterns 142-1 and 142-2. The second upper and lower coil patterns 142-1 and 142-2 may be formed to have a same coil pattern. An effect due to the shape of the second coil pattern 142 of the second coil unit 140 will be described below with reference to FIGS. 4 and 9.

Furthermore, referring to FIG. 2, the first coil unit 130 may include a plurality of first printed circuit boards 133-1 and 133-2 stacked in the third direction, and the first coil pattern 132 may be formed on the plurality of first printed circuit boards 133-1 and 133-2. Furthermore, the second coil unit 140 may include a plurality of second printed circuit boards 143-1 and 143-2 spaced from each other in the third direction, and the second coil pattern 142 may be formed on the plurality of second printed circuit boards 143-1 and 143-2. Furthermore, as shown in FIG. 2, in the planar transformer 100 of the present disclosure, the plurality of first printed circuit boards 133-1 and 133-2 may be stacked between the plurality of second printed circuit boards 143-1 and 143-2 spaced from each other. However, the embodiment of the present disclosure is exemplary, and the configuration of the planar transformer is not limited thereto.

Furthermore, each of the first printed circuit boards 133-1 and 133-2 may include the first upper and lower coil patterns 132-1 and 132-2 divided into upper and lower portions. Each of the second printed circuit boards 143-1 and 143-2 may include the second upper and lower coil patterns 142-1 and 142-2 divided into upper and lower portions.

Meanwhile, the first upper coil pattern 132-1 and the first lower coil pattern 132-2 may be electrically connected through via holes 134-1 and 134-2 passing through the plurality of first printed circuit boards 133-1 and 133-2. The via holes 134-1 and 134-2 may be provided to correspond to the plurality of first printed circuit boards 133-1 and 133-2, respectively. For example, a first via hole 134-1 may be formed in the first printed circuit board 133-1 on which the first upper coil pattern 132-1 is formed, and a second via hole 134-2 may be formed in the first printed circuit board 133-2 on which the first lower coil pattern 132-2 is formed. By including the electrical connection through the via holes 134-1 and 134-2 and spiral patterns of which the rotation directions are opposite to each other, the current flowing through the first coil unit 130 may flow in a consistent direction within the first coil unit 130.

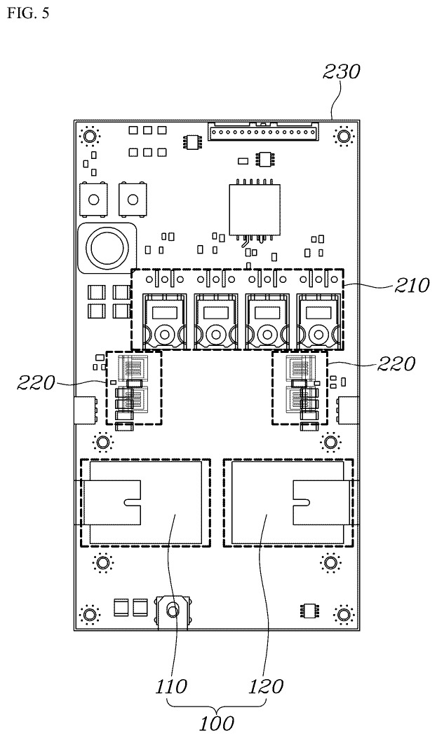

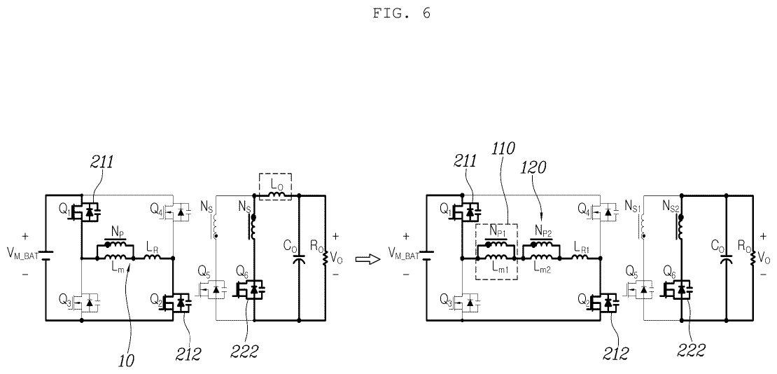

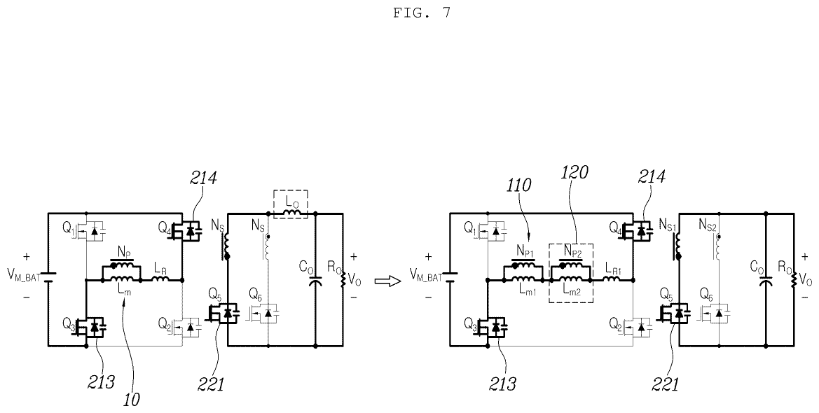

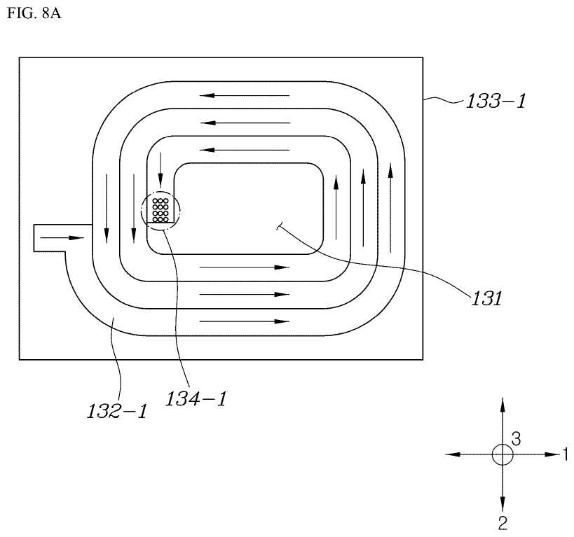

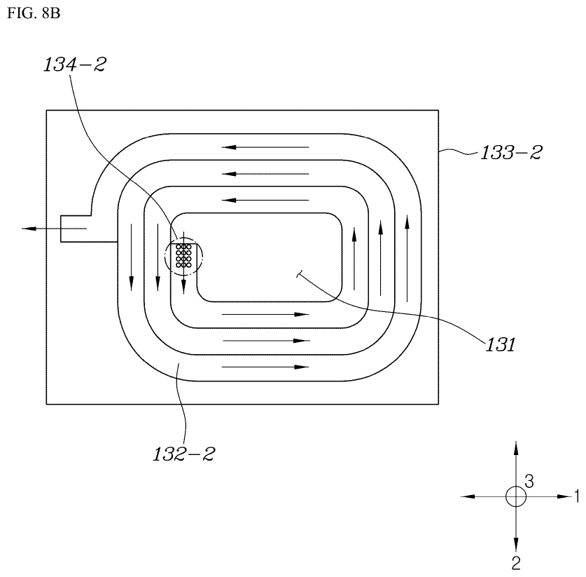

Hereinafter, a converter 200 to which the above-described planar transformer 100 is applied will be described with reference to FIG. 4, FIG. 5, FIG. 6, FIG. 7, FIG. 8, and FIG. 9. However, for convenience of explanation, the circuit diagrams shown in FIGS. 4, 6 and 7 may be circuit diagrams of a phase shift full bridge (PSFB) converter.

First, the converter 200 according to an exemplary embodiment of the present disclosure will be described with reference to FIG. 4 and FIG. 5.

FIG. 4 is a circuit diagram illustrating the configuration of a converter according to an exemplary embodiment of the present disclosure. FIG. 5 is a diagram illustrating a configuration of a substrate included in a converter according to an exemplary embodiment of the present disclosure.

Referring to FIG. 4, the converter 200 according to an exemplary embodiment of the present disclosure may have the planar transformer 100 according to the above-described embodiment, an AC terminal connected to one end portion of the planar transformer 100, and a DC terminal for receiving DC power. Furthermore, the converter 200 may include a primary switching unit 210 including a plurality of first switching elements 211, 212, 213 and 214, and a secondary rectifying unit 220 including one end portion connected to an opposite end portion of the planar transformer 100 and an opposite end portion connected to an output terminal. The primary switching unit 210 of the converter 200 may include the plurality of first switching elements 211, 212, 213 and 214, and may control ON/OFF states of the plurality of first switching elements 211, 212, 213 and 214 to provide AC power to the primary coil of the planar transformer 100, that is, the first coil unit 130. The secondary rectifying unit 220 may also include a plurality of second switching elements 221 and 222, and one of the plurality of second switching elements 221 and 222 may be selectively activated according to the flow direction of the current.

Furthermore, each component of the converter 200 may be mounted on a board. Referring to FIG. 5, the converter 200 according to an exemplary embodiment of the present disclosure may further include a substrate 230. Components included in the circuit diagram of the converter 200 shown in FIG. 4 may have various layouts and may be mounted on the substrate 230. For example, the secondary rectifying unit 220 of the converter 200 may be disposed in the center portion of the substrate 230, and the primary switching unit 210 may be disposed on one side of the secondary rectifying unit 220 on the substrate 230. The planar transformer 100 may be disposed at an opposite side of the secondary rectifying unit 220 on the substrate 230. However, the embodiment of the present disclosure is exemplary, and it may be obvious that the arrangement on the substrate 230 shown in FIG. 5 may be variously formed.

Meanwhile, the AC terminal of the primary switching unit 210 may be connected to the first coil unit 130 of the planar transformer 100, and one end portion of the secondary rectifying unit 220 may be connected to the second coil unit 140 of the planar transformer 100. Furthermore, the output terminal may be connected to the second coil unit 140 at a plurality of points A and B. This will be described with reference to FIG. 6 and FIG. 7.

FIG. 6 and FIG. 7 are diagrams illustrating circuit changes of a converter according to an exemplary embodiment of the present disclosure.

The circuit diagram shown on the left side of FIG. 6 and FIG. 7 is a circuit diagram of a converter according to a comparative example including a separate output inductor Lo. The circuit diagram shown on the right side of FIG. 6 and FIG. 7 is a circuit diagram of the converter 200 to which the planar transformer 100 according to the exemplary embodiment of the present disclosure is applied.

Referring to FIG. 6, when the (1-1)-th switching element 211 and the (1-2)-th switching element 212 among the plurality of first switching elements 211, 212, 213 and 214 included in the primary switching unit 210 are turned on, in the secondary rectifying unit 220, the (2-2)-th switching element 222 of the plurality of second switching elements 221 and 222 is turned on and the current is transmitted to the output terminal through the secondary rectifying unit 220. In a process of transmitting the current to the output terminal, the converter according to the comparative example includes a transformer 10 and an output inductor Lo formed of a single core. However, due to the output inductor Lo including a shape of a coil including a plurality of turns, the flow length of the current transmitted to the output terminal may be increased, and the loss of current in a process of transmitting the current to the output terminal may occur due to the load present on the output inductor Lo. To solve such problems, the converter 200 of the present disclosure removes the output inductor Lo and configures the planar transformer 100 including the plurality of core units 110 and 120 to replace the function of the output inductor Lo with the magnetizing inductance of the coil unit contained in one of the plurality of core units 110 and 120.

In detail, as shown in FIG. 6, when the (1-1)-th switching element 211 and the (1-2)-th switching element 212 are turned on, the second coil unit 140 included in the first core unit 110 is configured as the output inductor Lo instead. Referring to FIG. 4, it may be understood that the second coil unit 140 and the output terminal are connected at points A and B. For example, point A may be a point at which the second upper coil pattern 142-1 of the second coil unit 140 and the output terminal are connected, and point B may be a point at which the second lower coil pattern 142-2 of the second coil unit 140 and the output terminal are connected. Accordingly, when a current flows into the first coil unit 130, the current may be output to the output terminal through point A of the second coil unit 140 in the direction of current flowing into the second coil unit 140 due to the electromagnetic induction phenomenon and may be output to the output terminal through point B.

Furthermore, referring to FIG. 7, similarly to the case of FIG. 6, when the (1-3)-th switching element 213 and the (1-4)-th switching element 214 among the plurality of first switching elements 211, 212, 213 and 214 included in the primary switching unit 210 are turned on, the second coil unit 140 included in the second core unit 120 among the plurality core units 110 and 120 is configured as the output inductor Lo instead. However, the exemplary embodiment of the present disclosure is exemplary, and of course, the core units including the second coil unit 140 that performs the function of the output inductor Lo instead may be different from each other according to the patterns or arrangements of the first coil units 130 and the second coil units 140 included in the plurality of core units 110 and 120. The details of a current flow in the first coil unit 130 and the second coil unit 140 will be described with reference to FIG. 8 and FIG. 9.

FIGS. 8A and 8B are diagrams illustrating a current flow flowing through a first coil unit in a planar transformer according to an exemplary embodiment of the present disclosure. FIG. 9 is a diagram illustrating a current flow flowing through a second coil unit in a planar transformer according to an exemplary embodiment of the present disclosure.

For example, a current may flow through the first upper coil pattern 132-1 and the first lower coil pattern 132-2 included in the plurality of first printed circuit boards 133-1 and 133-2 in a counterclockwise direction thereof. Referring to FIG. 8A, the current input into one end portion of the first upper coil pattern 132-1 rotates counterclockwise along the first upper coil pattern 132-1, and is transmitted to the first lower coil pattern 132-2 through the first via hole 134-1 existing at an opposite end portion of the first upper coil pattern 132-1. Referring to FIG. 8B, the current transmitted to the first lower coil pattern 132-2 starts with the second via hole 134-2 of the first lower coil pattern 132-2 and rotates counterclockwise along the first lower coil pattern 132-2, being output to the end portion of the first lower coil pattern 132-2.

Referring to FIG. 9, as the current rotates counterclockwise as shown in FIGS. 8A and 8B, a clockwise current flow may occur in the second coil unit 140 included in the first core unit 110. As shown in FIG. 9, the reason why the current does not move along the second coil patterns 142-1 and 142-22 formed in the second coil unit 140 and exits at the middle is that the output terminal shown in FIG. 4 is connected to the second coil patterns 142-1 and 142-2 of the second coil unit 140 at the plurality of points A and B.

For example, when the current flow direction of the first coil unit 130 is counterclockwise as shown in FIGS. 8A and 8B, a clockwise current flow may be formed in the second coil unit 140 due to electromagnetic induction. As shown in FIG. 9, in the second upper coil pattern 142-1 or the second lower coil pattern 142-2, the current flowing clockwise (e.g., the direction of the solid arrow shown in FIG. 9) may be transmitted to the output terminal through point A or B. When the current flow direction of the first coil unit 130 is a clockwise direction (e.g., the direction opposite to the direction shown in FIGS. 8A and 8B), as shown in FIG. 9, the current flowing counterclockwise (e.g., a dotted arrow direction shown in FIG. 9) in the second upper coil pattern 142-1 or the second lower coil pattern 142-2 may be transmitted to the output terminal through point A or B.

As described above, unlike the first coil unit 130, the second coil unit 140 forms a single coil pattern, reducing the current flow length compared to the output inductor Lo. Furthermore, because the second coil pattern 142 of the second coil unit 140 has a shape including a larger area than the coil of the output inductor Lo, the second coil pattern 142 may have a lower internal resistance than the output inductor Lo, so that the current loss is reduced.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A planar transformer comprising:
a first core unit including a first receiving portion extending in a first direction thereof;
a second core unit spaced from the first core unit, disposed in parallel with the first core unit in a second direction thereof, and including a second receiving portion extending in the first direction;
a first coil unit including a first through hole formed in a center portion thereof, and a first coil pattern passing through the first receiving portion and the second receiving portion around the first through hole to form a turn; and
a second coil unit including a second through hole formed in a center portion thereof, and aligned with the first through hole in a third direction thereof, and a second coil pattern passing through the first receiving portion and the second receiving portion around the second through hole.

2. The planar transformer of claim 1,
wherein the first core unit includes a first leg and a second leg extending in the third direction and spaced from each other in the second direction, and
wherein the second core unit includes a first leg and a second leg extending in the third direction and spaced from each other in the second direction.

3. The planar transformer of claim 2, wherein the second leg of the first core unit and the first leg of the second core unit face each other in the second direction.

4. The planar transformer of claim 2, wherein the second leg of the first core unit and the first leg of the second core unit pass through the first through hole and the second through hole in the third direction.

5. The planar transformer of claim 1,
wherein the first core unit includes a first upper core and a first lower core coupled to each other in the third direction, and
wherein the second core unit includes a second upper core and a second lower core coupled to each other in the third direction.

6. The planar transformer of claim 1, wherein the first coil unit includes a plurality of first printed circuit boards stacked in the third direction.

7. The planar transformer of claim 1, wherein the second coil unit includes a plurality of second printed circuit boards spaced from each other in the third direction.

8. The planar transformer of claim 7, wherein the second coil pattern includes a second upper coil pattern and a second lower coil pattern, that form a single turn, respectively.

9. The planar transformer of claim 1, wherein the first coil pattern is formed in a plurality of turns and the second coil pattern is formed in a single pattern.

10. The planar transformer of claim 9, wherein the first coil pattern includes a first upper coil pattern and a first lower coil pattern that form a plurality of turns, respectively.

11. The planar transformer of claim 1,
wherein the first coil pattern includes a first upper coil pattern and a first lower coil pattern that form a plurality of turns, respectively.
wherein the second coil pattern includes a second upper coil pattern and a second lower coil pattern, that form a single turn, respectively, and
wherein the first coil pattern is disposed between the second upper coil pattern and the second lower coil pattern.

12. A converter comprising:
the planar transformer of claim 1,
a primary switching unit including an AC terminal connected to one end portion of the planar transformer and a DC terminal receiving DC power, the primary switching unit including a plurality of first switching elements; and
a secondary rectifying unit including one end portion connected to an opposite end portion of the planar transformer and an opposite end portion connected to an output end portion.

13. The converter of claim 12,
wherein the converter further includes a substrate, and
wherein the secondary rectifying unit is disposed in a center portion of the substrate, the primary switching unit is disposed at one side of the secondary rectifying unit on the substrate, and the transformer is disposed at an opposite side of the rectifying unit on the substrate.
